(19) United States
(12) Patent Application Publication
(10) Pub. No.: US 2017/0137928 A1
(43) Pub. Date: May 18, 2017

(54) METALLIC FILM AND MANUFACTURING METHOD OF METALLIC FILM

(71) Applicant: AISIN SEIKI KABUSHIKI KAISHA, Kariya-shi (JP)

(72) Inventors: Takashi HARA, Obu-shi (JP); Kosuke KATAYAMA, Takahama-shi (JP)

(73) Assignee: AISIN SEIKI KABUSHIKI KAISHA, Kariya-shi (JP)

(21) Appl. No.: 15/321,995

(22) PCT Filed: Sep. 24, 2015
(86) PCT No.: PCT/JP2015/076863

§ 371 Date: Dec. 23, 2016

(30) Foreign Application Priority Data
Sep. 26, 2014 (JP) 2014-196070

(51) Int. Cl. C23C 14/14; H01Q 1/32; C23C 14/24

(52) U.S. Cl. CPC C23C 14/14; C23C 14/24; E05B 81/77; H01Q 1/3283

(57) ABSTRACT

A metallic film includes an indium layer formed on a base material surface, where a mean area of an indium particle configuring the indium layer is equal to or smaller than 20000 nm². A manufacturing method of the metallic film includes an indium film formation process forming an indium layer on the base material surface by vapor-depositing indium on the base material surface, where in the indium film formation process, the indium is vapor-deposited on the base material surface in a state where a temperature of the base material surface is heated to a predetermined temperature.

### TECHNICAL FIELD

This invention relates to a metallic film and a manufacturing method of the metallic film.

### BACKGROUND ART

A smart handle provided at a vehicle includes a handle main body formed of a non-conductive resin base material, and an antenna and a touch sensor (a lock sensor, an unlock sensor) which are provided inside the handle main body. In addition, to enhance a design performance, a film (which will be hereinafter referred to as a metallic film) including metallic luster is formed at an outer surface of the handle main body (a base material).

The antenna provided inside the handle main body of the smart handle sends radio waves to a portable device positioned outside the handle main body, or receives radio waves from the portable device. Thus, the metallic film formed at the outer surface of the handle main body needs to include a high radio wave permeability so as not to inhibit communication by the radio waves between the antenna and the portable device. In addition, the touch sensor provided inside the handle main body of the smart handle detects a change of electrostatic capacity that is caused by, for example, a human hand being in contact with a predetermined position of the handle main body. Thus, the metallic film formed at the outer surface of the handle main body needs to include a high electrical insulating property so that the touch sensor does not erroneously detect the change of the electrostatic capacity that is caused by, for example, the human hand being in contact with a portion other than the predetermined position of the handle main body.

As a material of the metallic film including the high radio wave permeability and the high electrical insulating property, indium is often used. A thin film layer (an indium layer) formed of indium includes a layered configuration as small indium particles are arranged dispersedly. Accordingly, a small gap is formed between the adjacent indium particles in the indium layer. The radio wave permeability and the electrical insulating property are enhanced by the gap formed as described above. In addition, because brightness of the indium layer is high, indium is preferably used as the metallic film requiring the design performance.

Patent document 1 discloses a metallic film including an indium layer formed at a base material surface, a first top coat formed on the indium layer for enhancing adhesiveness of the indium layer and the base material with each other, and a second top coat formed on the first top coat for enhancing a weather resistance. Patent document 2 discloses a decorative film (metallic film) including a transparent resin film and an indium layer formed on a reverse surface of the transparent resin film.

### DOCUMENT OF PRIOR ART

### Patent Document

Patent document 1: JP2013-144902A
Patent document 2: JP 2007-285093A

### OVERVIEW OF INVENTION

### Problem to be Solved by the Invention

According to Patent document 1, a hue of the indium layer formed at the base member surface by, for example, vapor-depositing is tinged with yellow. The metallic film including such an indium layer gives a yellowish impression to an observer, and thus is undesirable as a decorative film. Therefore, according to Patent document 1, blue pigment is added into the top coat formed on the indium layer. Also in Patent document 2, similarly to Patent document 1, it is anticipated that the blue pigment needs to be added to the transparent resin film in order to approximate a hue of the indium layer to blue.

However, in a case where the blue pigment is added into the metallic film, problems arise that a material cost of the blue pigment and a manufacturing cost for adding the blue pigment increase. Purposes of this invention are to provide a metallic film which includes a high radio wave permeability and a high electrical insulating property, and includes an indium layer whose hue is made close to blue without much increment in a manufacturing cost and a material cost, and to provide a manufacturing method of such a metallic film.

### Means for Solving the Problem

The inventors of this invention found out that a hue of an indium layer depends on a mean area of an indium particle constituting the indium layer, that is, the hue of the indium layer is changed according to the mean area of the indium particle. Further, the inventors of this invention found out that the smaller the mean area of the indium particle constituting the indium layer is, the more the hue of the indium layer changes from a yellow side to a blue side.

According to the above-described findings, this invention provides a metallic film including an indium layer formed on a base material surface wherein a mean area of an indium particle configuring the indium layer is equal to or smaller than 20000 nm².

In a case where the mean area of the indium particle constituting the indium layer formed on the base material surface is equal to or smaller than 20000 nm², when a color of the indium layer is expressed by the L*a*b* color system, a b* value is negative. The b* value is an indicator indicating whether the hue is close to yellow or is close to blue. The larger the b* value is in the positive direction, the closer the hue is to yellow, and the larger the b* value is in the negative direction, the closer the hue is to blue. Accordingly, in a case where the mean area of the indium particle is equal to or smaller than 20000 nm², the b* value is a negative number, and thus the hue of the indium layer can be made to approach blue. As described above, according to this invention, by controlling the mean area of the indium particle included in the indium layer, the hue of the indium layer can be made close to blue without adding an additive including the blue pigment, for example. In addition, the indium layer includes the high radio wave permeability and the high electrical insulating property as described above. In consequence, according to this invention, the metallic film which includes the high radio wave permeability and the high electrical insulating property, and includes the indium layer whose hue is made close to blue without much increment in the manufacturing cost and the material cost is provided.

In this invention, “the mean area” of the indium particle is defined as an average value of an area of each of the indium particles shown in a planar image of the surface of the indium layer that is seen from one direction, specifically, a normal direction of the surface of the indium layer (a normal direction of a base material surface). For example, the average value of the area of the indium particle observed in a SEM image imaging the surface of the indium layer from the normal direction thereof corresponds to the mean area. In addition, in this invention, as long as the indium layer is formed on or above the base material surface, other layer can be interposed between the indium layer and the base material surface. For example, also in a case where a flat smooth layer that will be described later is formed between the base material surface and the indium layer, and the indium layer is formed on a surface of the flat smooth layer, it is interpreted according to this invention that the indium layer is formed on the base material surface. In addition, in this case, it can be also interpreted that the flat smooth layer is the base material.

In addition, the inventors of this invention found out that, in a case where the indium is vapor-deposited on the base material surface, a size of the indium particle depends on a temperature of the base material surface, that is, the mean area of the indium particle is changed according to the temperature of the base material surface. Further, the inventors also found that the higher the temperature of the base material surface (a vapor-deposited surface) is when the indium is vapor-deposited on the base material surface, the smaller the mean area of the indium particle becomes.

According to the above-described findings, this invention provides a manufacturing method of a metallic film including an indium layer formed on a base material surface, the manufacturing method including an indium film formation process forming an indium layer on the base material surface by vapor-depositing indium on the base material surface, wherein in the indium film formation process, the indium is vapor-deposited on the base material surface in a state where the base material surface is heated to a predetermined temperature corresponding to a temperature which allows a mean area of an indium particle configuring the indium layer formed on the base material surface to be equal to or smaller than 20000 nm².

According to this invention, the mean area of the indium particle configuring the indium layer formed on the base material surface is made equal to or smaller than 20000 nm² in a simple method of heating the base material to increase the temperature of the base material surface in the indium film formation process. Accordingly, the manufacturing method of the metallic film is provided, which includes the high radio wave permeability and the high electrical insulating property, and includes the indium layer whose hue is made close to blue without much increment in the manufacturing cost and the material cost.

In the above-described invention, the predetermined temperature corresponding to the temperature which allows the mean area of the indium particle configuring the indium layer formed on the base material surface to be equal to or smaller than 20000 nm² is a temperature which is equal to or higher than 50° C. That is, it is ideal that the indium is vapor-deposited at the base material surface in a state in which the temperature of the base material surface is heated to equal to or higher than 50° C. in the indium film formation process.

According to this, in the simple method of increasing the temperature of the base material surface to equal to or higher than 50° C. in the indium film formation process, the mean area of the indium particle configuring the indium layer formed in the indium film formation process can be made equal to or smaller than 20000 nm². Accordingly, the manufacturing method of the metallic film is provided, which includes the high radio wave permeability and the high electrical insulating property, and is provided with the indium layer whose hue is made close to blue without much increasing the manufacturing cost and the material cost.

The manufacturing method of the metallic film according to this invention ideally includes a flat smooth layer formation process of forming a flat smooth layer on the base material surface by applying resin paint to the base material surface and heating the paint that is applied. The indium film formation process is performed after the flat smooth layer formation process is performed, and the indium is vapor-deposited on the flat smooth layer in a case where a temperature of the flat smooth layer heated in the indium film formation process is equal to or higher than 50° C. According to this, the indium is vapor-deposited on the flat smooth layer that has been heated in the previous process (the flat smooth layer formation process), and thus the flat smooth layer does not need to be separately heated in the indium film forming process. Consequently, a time period of manufacturing process of the metallic film can be reduced and the manufacturing cost can be further reduced.

### BRIEF DESCRIPTION OF DRAWINGS

FIG. 1 is a cutaway plan view of an outside door handle for a vehicle.

FIG. 2 is a cross-sectional view taken along line II-II in FIG. 1.

FIG. 3 is a schematic cross-sectional view of a metallic film formed at an outer member.

FIG. 4 is an SEM image of an indium layer of the metallic film according to this embodiment.

FIG. 5 is a graph indicating a relationship between a mean area of an indium particle configuring the indium layer, and a b* value in a case where a color of the indium layer is expressed by the L*a*b* color system.

FIG. 6 is a graph indicating a relationship between the mean area of the indium particle configuring the indium layer, and an L* value in a case where the color of the indium layer is expressed by the L*a*b* color system.

FIG. 7 is a schematic view of a vacuum vapor deposit apparatus used in an indium film formation process.

FIG. 8A, 8B, 8C are SEM images of the indium layers of the metallic films according to respective examples.

### MODE FOR CARRYING OUT THE INVENTION

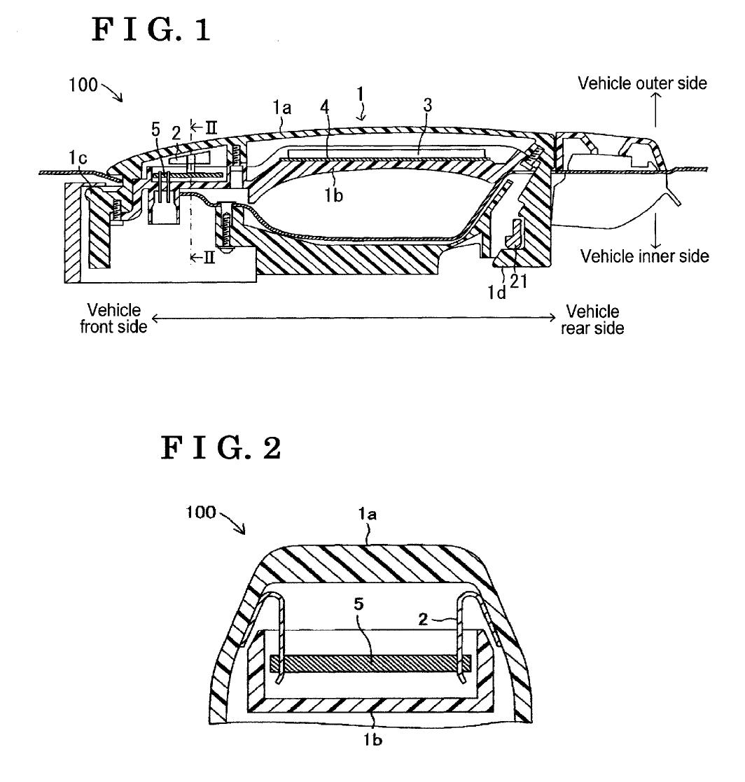

An embodiment of this invention will be described below. A metallic film according to the embodiment is formed on a surface of a handle main body of an outside door handle for a vehicle which serves as a smart handle. FIG. 1 is a cutaway plan view of an outside door handle 100 for a vehicle, which is provided with a handle main body 1 at which the metallic film is formed. FIG. 2 is a cross-sectional view taken along line II-II in FIG. 1. The outside door handle 100 for the vehicle is to be attached to a vehicle door.

The handle main body 1 provided at the outside door handle 100 for the vehicle includes an outer member 1a positioned at a vehicle outer side and an inner member 1b positioned at a vehicle inner side relative to the outer member 1a. A shaft portion 1c is formed at an end portion of the outer member 1a at a vehicle front side. The shaft portion 1c is for allowing the handle main body 1 to be pivotally supported at the vehicle door. A lock mechanism 21 for locking the vehicle door and an engaged piece 1d engageable with the lock mechanism 21 are provided at an end portion of the outer member 1a at a vehicle rear side. A void is formed between the outer member 1a and the inner member 1b. For example, a lock sensor (capacitance sensor) 2, an unlock sensor (capacitance sensor) 3, an antenna 4 and a substrate of a detection circuit (ECU 5) are arranged in the void and are fixed at the inner member 1b. The outer member 1a and the inner member 1b are fixed to each other with a screw at both end portions in a vehicle front and rear direction.

A request signal is sent constantly from the antenna 4. When a portable device positioned outside the vehicle receives the request signal, the portable device modulates an ID code of the signal and sends the signal of which the ID code is modulated. When the signal sent by the portable device is received by the antenna 4 again, the signal is demodulated and then is inputted into the ECU 5. The ECU 5 checks or collates the inputted ID code with an ID code stored at a memory. In a state where the ID code is checked, if the unlock sensor 3 detects a change in electrostatic capacity which is caused by a user's touching a predetermined portion of the handle main body 1, the vehicle door is unlocked. In addition, in a state where the ID code is checked, if the lock sensor 2 detects the change in the electrostatic capacity which is caused by the user's touching the predetermined portion of the handle main body 1, the vehicle door is locked. The receiving antenna may be arranged at other position than the handle main body 1, for example, in a pillar.

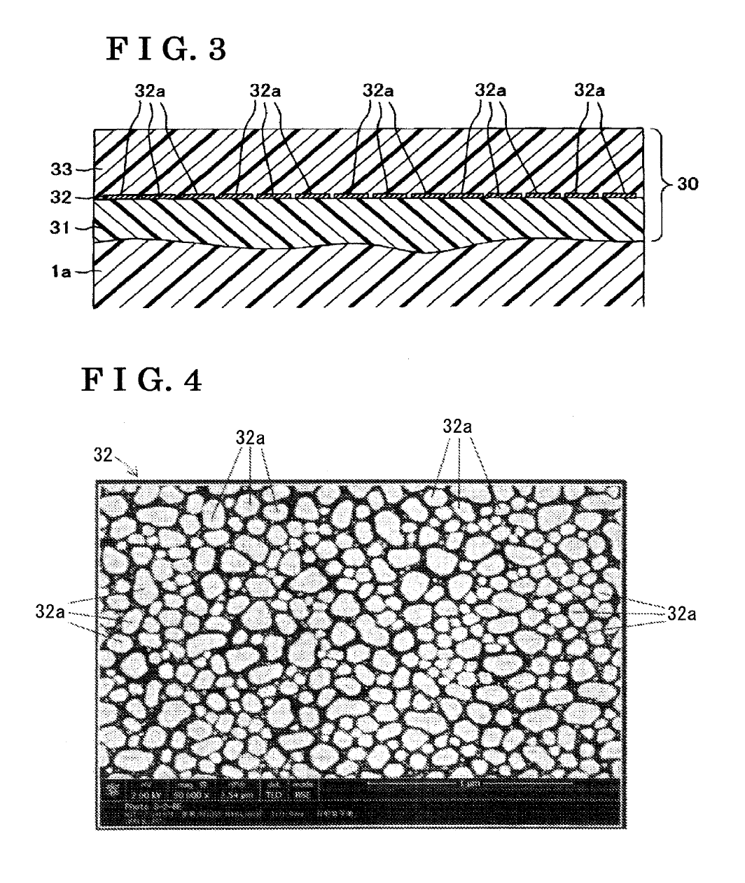

The outer member 1a of the handle main body 1 is manufactured by mold-injecting alloy resin (polymer alloy) of PC (polycarbonate) resin and PBT (polybutylene terephthalate) resin which are insulating resin. The metallic film according to the embodiment is formed on a surface (a face facing the vehicle outer side) of the outer member 1a. FIG. 3 is a schematic cross-sectional view of a metallic film 30 formed at the outer member 1a. As illustrated in FIG. 3, the metallic film 30 includes a flat smooth layer 31 formed on a surface of the outer member 1a (a base material), an indium layer 32 formed on the flat smooth layer 31 and a protection layer 33 covering the indium layer 32.

The flat smooth layer 31 is formed on the surface of the outer member 1a with the aim of more smoothing the surface of the outer member 1a, and a thickness of the flat smooth layer 31 is approximately 20 μm. For example, acrylic urethane based paint is used as the flat smooth layer 31. The indium layer 32 is formed on the flat smooth layer 31 by vapor-depositing. A thickness of the indium layer 32 is approximately 30 nm. The protection layer 33 is formed on the indium layer 32 so as to cover the indium layer 32, thereby protecting the indium layer 32. For example, acrylic urethane based paint is used as the protection layer 33. A thickness of the protection layer 33 is approximately 20 μm.

The protection layer 33 is transparent. Thus, when the metallic film 30 is seen from the vehicle outer side, the indium layer 32 is visually recognizable. The indium layer 32 includes metallic luster. The metallic luster of the indium layer 32 enhances a design performance of the handle main body 1.

FIG. 4 is an SEM image (at a magnification of 50000 times) of the indium layer 32 of the metallic film 30 according to this embodiment, which is seen from a direction that is perpendicular to the surface of the indium layer 32 (that is, from a normal direction). As illustrated in FIG. 4, the indium layer 32 is formed of an assembly of small indium particles 32a. The assembly is formed by the indium particles 32a which gather together but do not agglutinate to be equal to or greater than a predetermined size. In addition, a small void is formed between the adjacent indium particles 32a, 32a. Due to the formation of the void, a radio wave permeability is enhanced. In addition, because the small void is formed, each of the indium particles 32a is prevented from being electrically connected to one another. In consequence, an electrical insulating property is enhanced.

It is considered that a characteristic diameter of the indium particle 32a shown in FIG. 4 is approximately 0.1 μm (100 nm). According to the image shown in FIG. 4, an area of each of the indium particles 32a is considered to be approximately 10000 nm² to 20000 nm². That is, an average value of the area (which will also be referred to as an average island area) of the indium particle which is seen from a direction indicated in FIG. 4 is equal to or smaller than 20000 nm².

In a case where a color of the metallic film 30 according to the embodiment, that is, a color of the indium layer 32 in the metallic film 30, is expressed by the L*a*b* color system standardized by International Commission on illumination (CIE), a b* value is negative. The b* value represents a hue. The hue is close to yellow in a case where the b* value is large in the positive direction, and the hue is close to blue in a case where the b* value is large in the negative direction. As the b* value of the metallic film 30 of the embodiment is a negative number, the indium layer 32 includes a bluish color.

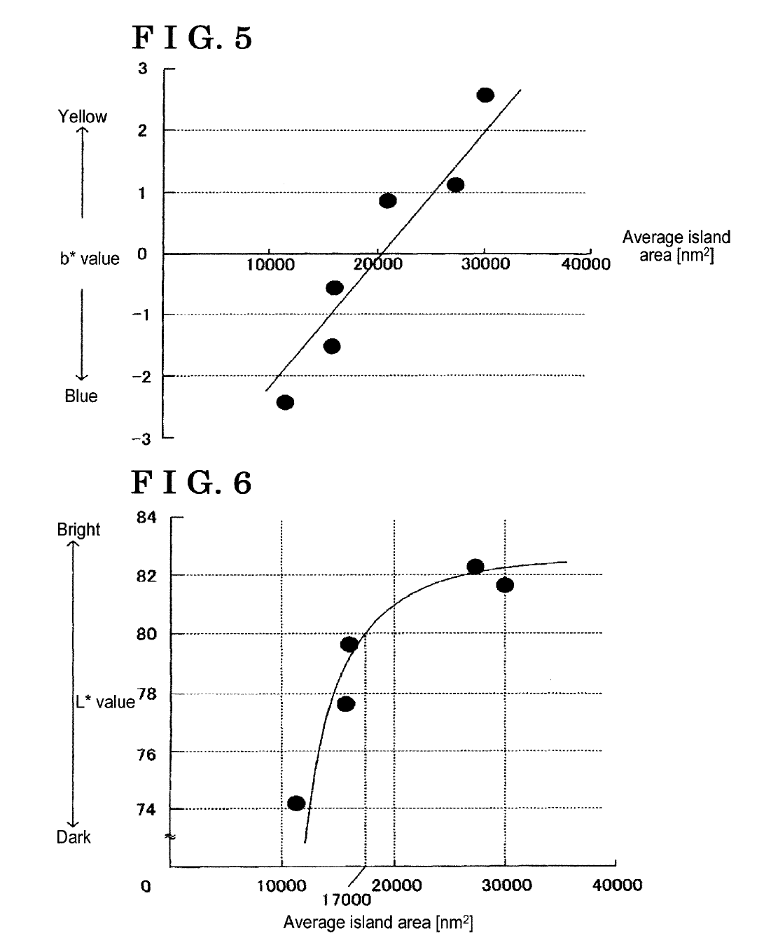

FIG. 5 is a graph indicating a relationship between a mean area (an average island area) of the indium particle 32a configuring the indium layer 32, and the b* value in a case where the color of the indium layer 32 is expressed by the L*a*b* color system. As can be seen from FIG. 5, the b* value changes depending on the average island area. Specifically, the smaller the average island area is, the smaller the b* value is. In addition, the b* value is a negative number in a case where the average island area is equal to or smaller than 20000 nm². Further, in a range in which the average island area is equal to or smaller than 20000 nm², the smaller the average island area is, the larger the b* value is in the negative direction. That is, the indium layer 32 presents the bluish color in a case where the average island area is equal to or smaller than 20000 square nanometers.

It can be considered that the reason why the b* value changes depending on the average island area is due to a local-field plasmon resonance phenomenon. That is, in a case where a metal nanoparticle is irradiated with light, a reflection ratio of light including a specific wavelength in a visible light region increases due to a plasmon resonance phenomenon. The wavelength of the light, of which the reflection ratio increases, changes depending on a size of the metallic nanoparticle. Specifically, the larger the size of the metal nanoparticle is, the reflection ratio of the light including the longer wave length increases. The smaller the size of the metal nanoparticle is, the reflection ratio of the light including the shorter wave length increases. In the visible light region, the light including a long wavelength is tinged with yellow and the light including a short wavelength is tinged with blue. Therefore, the smaller the size of the metal nanoparticle is, that is, the smaller the average island area of the indium particle is, the reflection ratio of the light including the shorter wavelength increases, that is, the reflection ratio of the light tinged with blue increases. As a result, the light tinged with the blue is observed. In a case where the average island area is equal to or smaller than 20000 nm², the b* value is a negative number, and accordingly the indium layer 32 presents the bluish color.

FIG. 6 is a graph indicating a relationship between the mean area (the average island area) of the indium particle 32a configuring the indium layer 32, and an L* value in a case where the color of the indium layer 32 is expressed by the L*a*b* color system. The L* value indicates brightness. The larger the L* value is, the higher the brightness is. As can be seen from FIG. 6, the larger the average island area is, the higher the L* value is. In addition, in a case where the average island area is equal to or larger than 17000 nm², the L* value is equal to or larger than 80. In a case where a color of a decorative chrome plating, which is often used for painting an exterior part of a vehicle, is expressed by the L*a*b* color system, the L* value is approximately from 80 to 84 and the b* value is approximately −0.5. Consequently, in a case where the average island area is equal to or larger than 17000 nm² and equal to or smaller than 20000 nm², the metallic film including the indium layer having the brightness and hue which are close to the decorative chrome plating. Therefore, in a case where peripheral parts and components of the handle main body 1 related to the embodiment are plated with the decorative chrome plating, the brightness and hue of these decorative chrome plated parts and the brightness and hue of the handle main body 1 can be matched with each other.

As described above, by forming the indium layer 32 in such a manner that the average island area of the indium particle 32a forming the indium layer 32 is equal to or smaller than 20000 nm², the metallic film 30 including the blueish hue. In addition, by forming the indium layer 32 in such a manner that the average island area of the indium particle 32a forming the indium layer 32 is equal to or larger than 17000 nm² and equal to or smaller than 20000 nm², the metallic film 30 including a high brightness and having the hue tinged with blue.

Next, a manufacturing method of the metallic film 30 according to the embodiment will be described. The metallic film 30 according to the embodiment is manufactured through (1) a flat smooth layer formation process, (2) an indium film formation process, and (3) a protection layer formation process.

(1) Flat Smooth Layer Formation Process

In the flat smooth layer formation process, acrylic urethane paint is applied to the surface (a surface facing the vehicle outer side) of the outer member 1a serving as the base material by, for example, spraying. Thereafter, the applied paint is heated and hardened. By being heated, the paint is baked onto the surface of the outer member 1a, and thus the flat smooth layer 31 is formed at the surface of the outer member.

(2) Indium Film Formation Process

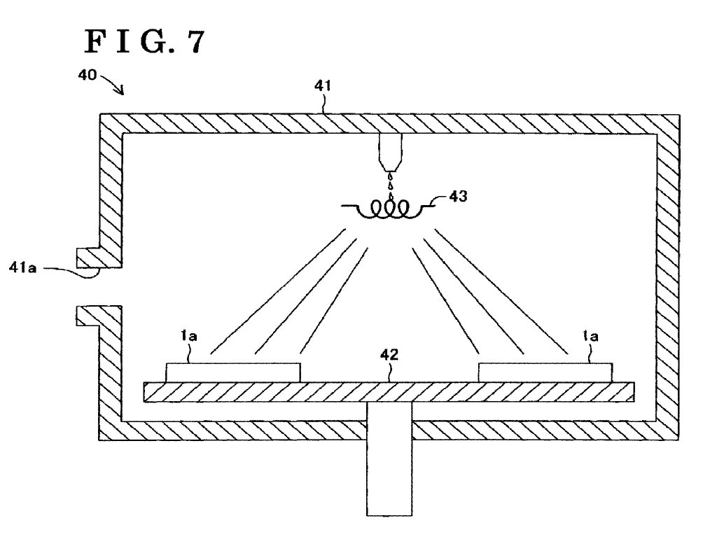

In the indium film formation process, by vapor-depositing indium on the surface (the base material surface) of the outer member 1a, to be precise, by vapor-depositing indium on the surface of the flat smooth layer 3a formed on the surface of the outer member 1a, the indium layer 32 is formed on the base material surface. FIG. 7 is schematic view of a vacuum vapor deposit apparatus 40 used in the indium film formation process. As illustrated in FIG. 7, the vacuum vapor deposit apparatus 40 includes a case 41 including a void formed inside thereof, a table 42 arranged in the case 41 and a filament 43 serving as a source of heat. The table 42 is provided at a lower portion of the void in the case 41. The outer member 1a, which serves as the base material, of the handle main body 1 is placed on the table 42. FIG. 7 illustrates a state in which plural outer members 1a are loaded on the table 42. The filament 43 is made of tungsten and is arranged at an upper portion in the void in the case 41. The case 41 is formed with an exhaust outlet 41a.

In a case where the indium film formation process is performed with the use of the above-described vacuum vapor deposit apparatus 40, first, a vacuum pump is connected to the exhaust outlet 41a and the vacuum pump is actuated. Accordingly, the void in the case 41 is brought into a high-vacuum state. Next, the filament 43 is electrified, and thus the filament 43 is heated. Thereafter, the indium, which is liquefied, is dropped at the filament 43. Thus, the indium is heated by the filament 43 and is vaporized. The vaporized indium comes in contact with the outer member 1a placed on the table 42 and is vapor-deposited onto the surface of the outer member 1a. Accordingly, the indium layer 32 is formed of the vapor-deposited indium. In the embodiment, a thickness of the formed indium layer 32 is approximately 30 nm.

Here, in the embodiment, in the indium film formation process, the surface (the surface of the flat smooth layer 31) of the outer member 1a serving as the base material, that is, a vapor-deposited surface, is heated to a temperature which is equal to or higher than 50° C. In this case, because the flat smooth layer 31 has been heated in the previous flat smooth layer formation process, as source of heat, the heat (residual heat) of the flat smooth layer 31 heated in the flat smooth layer formation process may be utilized. Specifically, in the indium film formation process, the indium is vapor-deposited on the surface of the flat smooth layer 31 when a temperature of the flat smooth layer 31 heated in the flat smooth layer formation process is equal to or higher than 50° C. As described, by vapor-depositing the indium on the flat smooth layer that has been heated in the previous process (the flat smooth layer formation process), the flat smooth layer does not need to be further heated separately in the indium film forming process.

A correlation exists between the temperature of the base material surface (the vapor-deposited surface) in the indium film formation process and the average island area of the indium particle 32a forming the indium layer 32 formed by the vapor-deposition. That is, the average island area of the indium particle 32a is changed depending on the temperature of the base material surface (the vapor-deposited surface) at a time of the vapor-depositing. Specifically, the higher the temperature of the base material surface (the vapor-deposited surface) becomes, the smaller the average island area of the indium particle 32a becomes. Consequently, in the indium film formation process, by vapor-depositing the indium on the base material surface in a state where the base material surface is heated to a predetermined temperature which is predetermined as a temperature allowing the average island area of the indium particle configuring the indium layer formed on the base material surface to be equal to or smaller than 20000 nm², the average island area of the indium particle 32a is made to be equal to or smaller than 20000 nm². In particular, in a case where the temperature of the base material surface (the vapor-deposited surface) at the vapor-depositing is equal to or higher than 50° C., the average island area of the indium particle 32a can be made to be equal to or smaller than 20000 nm². As described above, in a case where the average island area of the indium particle 32a is equal to or smaller than 20000 nm², the b* value representing the hue of the indium layer 32 is a negative number, that is, a number which is smaller than zero. In consequence, the indium layer that is tinged with blue can be obtained. That is, in the indium film formation process, by vapor-depositing the indium on the base material surface in a state where the temperature of the base material surface (the vapor-deposited surface) is heated to the temperature that is equal to or higher than 50° C., the metallic film 30 including the bluish indium layer 32 can be obtained.

The reason why the average island area of the indium particle 32a forming the indium layer 32 decreases as the base material surface temperature increases is not always clear, however, the following presumption may be made. That is, in a case where the base material surface temperature is low, the vaporized indium is cooled down after reaching the base material surface and is deprived of energy, and thus the vaporized indium cannot move on the base material surface. Consequently, the indium that is vapor-deposited between the two adjacent indium particles which are formed on the base material surface including the low temperature becomes hardened at the position, thereby filling a gap between the two adjacent indium particles. As a result that the gap is filled with the vapor-deposited indium, the two adjacent indium particles join each other to form a large indium particle. Therefore, it can be considered that the average island area of the indium particle becomes large. On the other hand, in a case where the base material surface temperature is high, the vaporized indium can move on the base material surface after reaching the base material surface. Thus, the indium vapor-deposited between the two adjacent indium particles formed on the base material surface including the high temperature moves on the base material surface so as to gather together with either one of the two adjacent indium particles. Consequently, the two adjacent indium particles do not join together with each other. As described above, in a case where the base material surface temperature is high, a probability that the adjacent indium particles join together with each other is low, and thus it is considered that the average island area of the indium particle is smaller compared to a case where the base material surface temperature is low.

(3) Protection Layer Formation Process

In the protection layer formation process, the protection layer 33 is formed on the indium layer 32 so as to cover the indium layer 32. In this case, acrylic urethane based paint is applied by, for example, spraying. Thereafter, the applied paint is heated, and then is hardened or cured. Thus, the paint is baked onto the surface of the indium layer 32, and thus the transparent protection layer 33 is formed on the indium layer 32.

### Example

First, acrylic urethane based paint was applied to a surface of a resin base material made of alloy resin (polymer alloy) of PC resin and PBT resin, and the applied paint was heated and hardened, thereby forming the flat smooth layer on the surface of the resin base material (the flat smooth layer formation process). Next, the resin base material formed with the flat smooth layer was heated to 60° C. and was placed on the table 42 of the vacuum vapor deposit apparatus 40 illustrated in FIG. 7. By operating the vacuum vapor deposit apparatus 40, the indium layer including a thickness of 30 nm was formed by vapor-deposition on the surface of the resin base material (the surface of the flat smooth layer) that has been heated to 60° C. (the indium film formation process). After the indium layer was formed, the resin base material was taken out of the vacuum vapor deposit apparatus 40 and acrylic urethane based paint was applied to the surface of the indium layer. Then, the applied paint was heated to be hardened, and thus the protection layer was formed on the indium layer (the protection layer formation process). Through the above-described processes, the metallic film according to the example was manufactured.

### Comparison Example 1

First, acrylic urethane based paint was applied to the surface of the resin base material made of alloy resin (polymer alloy) of PC resin and PBT resin, and the applied paint was heated and hardened, thereby forming the flat smooth layer on the surface of the resin base material. Next, the resin base material formed with the flat smooth layer was heated to 40° C. and was placed on the table 42 of the vacuum vapor deposit apparatus 40 illustrated in FIG. 7. By operating the vacuum vapor deposit apparatus 40, the indium layer including the thickness of 30 nm was formed by vapor-deposition on the surface of the resin base material (the surface of the flat smooth layer) that has been heated to 40° C. After the indium layer was formed, the resin base material was taken out of the vacuum vapor deposit apparatus 40 and acrylic urethane based paint was applied to the surface of the indium layer. Then, the applied paint was heated to be hardened, and thus the protection layer was formed on the indium layer. Through the above-described processes, the metallic film according to the comparison example 1 was manufactured.

### Comparison Example 2

First, acrylic urethane based paint was applied to the surface of the resin base material made of alloy resin (polymer alloy) of PC resin and PBT resin, and the applied paint was heated and hardened, thereby forming the flat smooth layer on the surface of the resin base material. Next, in a normal temperature state, the resin base material formed with the flat smooth layer was placed on the table 42 of the vacuum vapor deposit apparatus 40 illustrated in FIG. 7. By operating the vacuum vapor deposit apparatus 40, the indium layer including the thickness of 30 nm was formed on the surface of the resin base material (the surface of the flat smooth layer) of the normal temperature (25° C.) by vapor-deposition. After the indium layer was formed, the resin base material was taken out of the vacuum vapor deposit apparatus 40 and acrylic urethane based paint was applied to the surface of the indium layer. Then, the applied paint was heated and hardened, and thus the protection layer was formed on the indium layer. Through the above-described processes, the metallic film according to the comparison example 2 was manufactured.

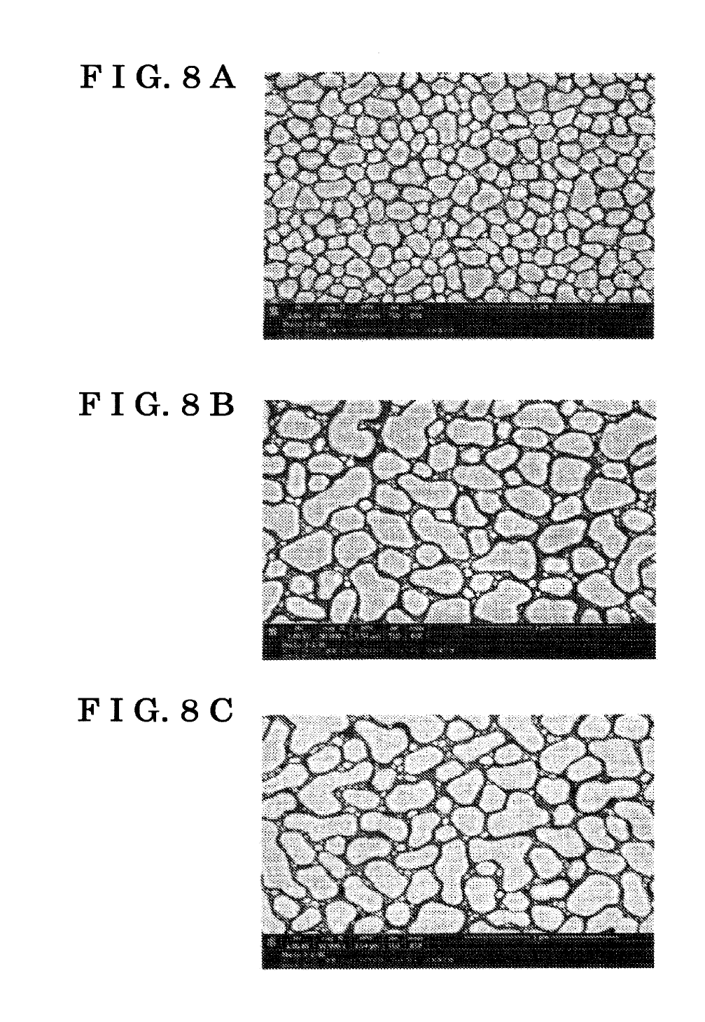

FIGS. 8A, 8B and 8C are SEM images (at a magnification of 50000 times) of the indium layers of the metallic films according to the respective examples (the example, the comparison example 1 and the comparison example 2), each of which is imaged from a normal direction of the surface of the indium layer. FIG. 8A is the SEM image of the indium layer of the metallic film according to the example, FIG. 8B is the SEM image of the indium layer of the metallic film according to the comparison example 1, and FIG. 8C is the SEM image of the indium layer of the metallic film according to the comparison example 2. As seen from FIGS. 8A, 8B and 8C, the average island area indicating the size of the indium particle forming the indium layer of the metallic film according to the example is smaller than the average island area indicating the size of the indium particle forming the indium layer of the metallic film according to the comparison example 1. In addition, the average island area indicating the size of the indium particle forming the indium layer of the metallic film according to the comparison example 1 is smaller than the average island area indicating the size of the indium particle forming the indium layer of the metallic film according to the comparison example 2. Consequently, it is found that the higher the base material surface temperature is at a time of vapor-depositing the indium on the base material surface, the smaller the average island area of the indium particle becomes.

Table 1 shows the heating temperature of the base material when forming the indium layer, a measurement result of the color of the indium layer, a result of a functional evaluation of the antenna and a result of a functional evaluation of the touch sensor, with regard to the respective metallic films according to the example, the comparison example 1 and the comparison example 2. For the measurement of the color, the spectrocolorimeter CM-700d of Konica Minolta, Inc. was used, and each value of the L*a*b* color system was measured. Out of the measured values, the L* value and the b* value are shown in Table 1. “Antenna functional evaluation” is an evaluation based on whether or not the antenna, which is arranged inside the handle main body including on the surface thereof the metallic film according to each example, is capable of normally communicating with the portable device outside. It was evaluated as passed (◯) in a case where the antenna and the portable device communicated with each other in a normal way. It was evaluated as failed (x) in a case where the antenna and the portable device did not communicate with each other in a normal way. In a case where the antenna functional evaluation is passed (◯), it can be determined that the metallic film includes the high radio wave permeability. “Touch sensor functional evaluation” is an evaluation based on whether or not the lock sensor and the unlock sensor which are arranged inside the handle main body malfunction related to locking and unlocking of the vehicle door, in a case where a human hand is in contact with a position other than a predetermined position of the smart handle provided with the handle main body including on the surface thereof the metallic film according to each example. It was evaluated as passed (◯) in a case where the malfunction did not occur. It was evaluated as failed (x) in a case where the malfunction occurred. In a case where the touch sensor functional evaluation is passed (◯), it can be determined that the metallic film includes the high electrical insulating property.

TABLE 1

| | Base material | Color of | | Antenna | Touch sensor |
|---|---|---|---|---|---|
| | surface | indium layer | | functional | functional |
| | temperature | L* | b* | evaluation | evaluation |
| Example | 60° C. | 84.72 | −0.19 | ◯ | ◯ |
| Comparison | 40° C. | 84.85 | 2.39 | ◯ | ◯ |
| example 1 | | | | | |
| Comparison | 25° C. | 84.90 | 1.93 | ◯ | ◯ |
| example 2 | | | | | |

As shown in Table 1, in each of the example, the comparison example 1 and the comparison example 2, the antenna functional evaluation and the touch sensor functional evaluation were passed (◯) and the L* value was a high value. With regard to the b* value, however, only the b* value related to the metallic film according to the example was the minus number (−0.19), and the b* values related to the metallic films according to the comparison example 1 and the comparison example 2 were the positive numbers (2.39, 1.93). Accordingly, it is found that the metallic film including the indium layer tinged with blue can be obtained in a case where the base material surface is heated to 60° C. in the indium film formation process. In the above-described example, the temperature of the base material surface before the indium is vapor-deposited is approximately 60° C., but it is considered that the temperature of the base material surface has been decreased approximately to 50° C. when the indium is actually being vapor-deposited. Consequently, it is considered that the bluish indium layer is formed if the temperature of the base material surface is equal to or higher than 50° C. at the time of vapor-deposition.

As described above, according to the metallic film related to the embodiment, by making the average island area of the indium particle forming the indium layer to be equal to or smaller than 20000 nm², the hue of the indium layer can approach to blue without the addition of the additive including the blue pigment as is conventionally performed. Consequently, the metallic film is provided, which includes the high radio wave permeability and the high electrical insulating property, and is provided with the indium layer whose hue is made close to blue without much increment in the manufacturing cost and the material cost.

In addition, the manufacturing method of the metallic film related to the embodiment includes the indium film formation process forming the indium layer on the base material surface by vapor-depositing the indium on the base material surface. In the indium film formation process, the indium is vapor-deposited on the base material surface in a state where the base material surface is heated to the predetermined temperature that is determined in advance as the temperature which causes the mean area of the indium particle configuring the indium layer formed on the base material surface to be equal to or smaller than 20000 nm². For example, the predetermined temperature is the temperature equal to or higher than 50° C., or ideally equal to or higher than 60° C. As described above, the mean area of the indium particle configuring the indium layer formed is made equal to or smaller than 20000 nm² by the simple method of heating the base material and increasing the temperature of the base material to, for example, equal to or higher than 50° C. in the indium film formation process. Accordingly, the manufacturing method of the metallic film is provided, which includes the high radio wave permeability and the high electrical insulating property, and includes the indium layer whose hue is made close to blue without much increment in the manufacturing cost and the material cost.

The embodiment of this invention is described as observed above, however, this invention is not limited to the above-described embodiment. For example, in the above-described embodiment, the example is shown in which the metallic film is formed on the surface of the outer member of the outside door handle for the vehicle which corresponds to the smart handle, however, this invention is applicable to other component which includes high radio wave permeability and electrical insulating property, and is required to have a design performance. For instance, recently, when a hand is held over an emblem provided at a back door of an automobile, for example, the back door opens. In such a case, the metallic film related to this invention can be formed on the emblem. In addition, this invention is applicable to a purpose other than the automobile, for example, this invention is applicable to a handle portion of a door of a residential building. As described above, this invention can be changed or modified without departing from the scope thereof.

1. (canceled)

2: A manufacturing method of a metallic film including an indium layer formed on a base material surface, the manufacturing method comprising:
an indium film formation process forming an indium layer on the base material surface by vapor-depositing indium on the base material surface, wherein
in the indium film formation process, the indium is vapor-deposited on the base material surface in a state where the base material surface is heated to a predetermined temperature corresponding to a temperature which allows a mean area of an indium particle configuring the indium layer formed on the base material surface to be equal to or smaller than 20000 nm², the predetermined temperature being a temperature which is equal to or higher than 50° C.

3. (canceled)

4: The manufacturing method of the metallic film according to claim 2, comprising:
a flat smooth layer formation process of forming a flat smooth layer on the base material surface by applying resin paint to the base material surface and heating the applied paint; wherein
the indium film formation process is performed after the flat smooth layer formation process is performed, and
the indium is vapor-deposited on the flat smooth layer in a case where a temperature of the flat smooth layer heated in the flat smooth layer formation process is equal to or higher than 50° C.
